(19) United States
(12) Patent Application Publication
(10) Pub. No.: US 2015/0263023 A1
(43) Pub. Date: Sep. 17, 2015

(54) NONVOLATILE SEMICONDUCTOR STORAGE DEVICE AND METHOD OF MANUFACTURING THE SAME

(71) Applicant: KABUSHIKI KAISHA TOSHIBA, Minato-ku (JP)

(72) Inventor: Takayuki TOBA, Yokkaichi (JP)

(73) Assignee: KABUSHIKI KAISHA TOSHIBA, Minato-ku (JP)

(21) Appl. No.: 14/529,851

(22) Filed: Oct. 31, 2014

Related U.S. Application Data
(60) Provisional application No. 61/950,885, filed on Mar. 11, 2014.

(51) Int. Cl. H01L 27/115; H01L 23/528; H01L 29/792; H01L 29/66; H01L 21/768; H01L 29/788; H01L 29/51

(52) U.S. Cl. CPC H01L 27/11548; H01L 29/788; H01L 23/528; H01L 29/518; H01L 29/66825; H01L 29/6656; H01L 21/76892; H01L 27/11524; H01L 27/11519; H01L 29/513; H01L 29/792; H01L 29/66833; H01L 27/1157; H01L 27/11565; H01L 27/11575

(57) ABSTRACT

A nonvolatile semiconductor storage device is provided with bit-line contacts extending through an interlayer insulating film disposed between two select gate transistors disposed so as to face one another in a portion where memory-cell units reside adjacent to one another in a first direction and electrically connecting a semiconductor substrate with bit lines in upper layers, wherein three or more of the bit-line contacts adjacent in a second direction and displaced from one another in the first direction are grouped as a layout pattern, and wherein among the bit-line contacts of the layout pattern, bit-line contacts located at two end portions in the first direction are provided so as to overlap with gate electrodes of the select gate transistors via an insulating film.

### CROSS-REFERENCE TO RELATED APPLICATION(S)

This application is based upon and claims the benefit of priority from U.S. Provisional Patent Application No. 61/950,885, filed on, Mar. 11, 2014 the entire contents of which are incorporated herein by reference.

### FIELD

Embodiments disclosed herein relate to a nonvolatile semiconductor storage device and a method of manufacturing the same.

### BACKGROUND

With advances in the miniaturization of memory cells in a NAND flash memory device, which is one example of a nonvolatile semiconductor storage device, bit-line contacts are being formed so as to be shaped like an elongate ellipse. The bit-line contacts are formed into an ellipse shape in order to secure sufficient area of contact with the semiconductor substrate and compensate for the shrunk pattern width. It is possible to inhibit increase of contact resistance by securing sufficient area of contact with the semiconductor substrate. When the distance between the adjacent bit-line contacts become close together, it becomes difficult to form the bit-line contacts next to one another. Thus, in order to secure a spacing of a certain amount or more, a plurality of bit-line contacts displaced in the bit-line direction are grouped into a layout pattern. Thus, increased number of displaced bit-line contacts in concert with the bit-line contacts being shaped into an elongate ellipse shape lead to an increase in the spacing between the select gate electrodes, thereby reducing the shrinking effect of the memory cells.

### BRIEF DESCRIPTION OF THE DRAWINGS

FIG. 1 is one example of an equivalent circuit schematically illustrating an electrical configuration of a memory-cell region of a first embodiment.

FIG. 2A illustrates a layout of the memory-cell region and is one example of a plan view looking down on the upper surfaces of an interlayer insulating film and contact plugs.

FIG. 2B illustrates a layout of the memory-cell region and is one example of a plan view with the interlayer insulating film and the contact plugs removed.

FIG. 3 is one example of a vertical cross-sectional side view taken along line 3-3 of FIG. 2A as viewed in the direction of the arrows.

FIG. 4A corresponds to FIG. 2A and FIG. 4B corresponds to FIG. 2A in case the contact plugs are formed into similar shapes and is one example of a comparative view.

FIG. 5 to FIG. 12 illustrate one phase of a manufacturing process flow and are examples of vertical cross-sectional side views taken along line 5-5 of FIG. 2A.

FIG. 13 illustrates a layout of a memory-cell region of a second embodiment and is one example of a plan view looking down on the upper surfaces of an interlayer insulating film and contact plugs.

### DESCRIPTION

In one embodiment, a nonvolatile semiconductor storage device configured by memory-cell units aligned in a first direction and aligned in a second direction crossing the first direction over an insulating region, each of the memory-cell units having memory-cell transistors aligned in the first direction and select gate transistors located at two end portions thereof is provided with bit-line contacts extending through an interlayer insulating film disposed between two select gate transistors disposed so as to face one another in a portion where the memory-cell units reside adjacent to one another in the first direction and electrically connecting a semiconductor substrate with bit lines in upper layers; wherein three or more of the bit-line contacts adjacent in the second direction and displaced from one another in the first direction are grouped as a layout pattern, and wherein among the bit-line contacts of the layout pattern, bit-line contacts located at two end portions in the first direction are provided so as to overlap with gate electrodes of the select gate transistors via an insulating film.

### First Embodiment

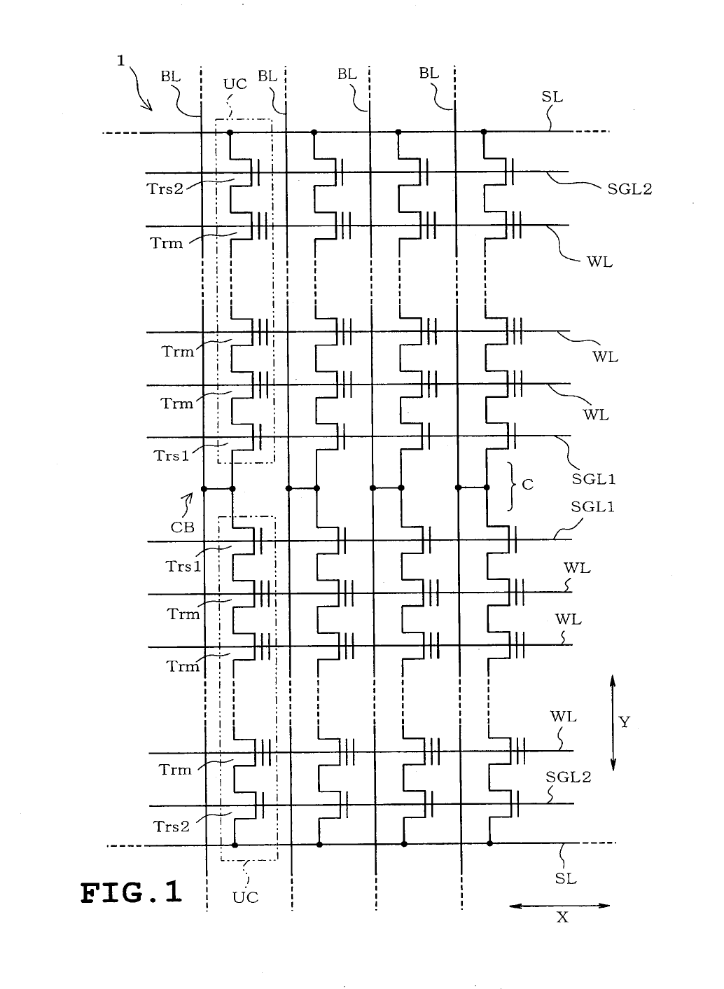

A first embodiment is described hereinafter through a NAND flash memory device application with reference to FIG. 1 to FIG. 12. The drawings are schematic, and the correlation of thickness to planar dimensions, the ratio of thicknesses of each of the layers, or the like are not necessarily consistent with the actual measurements. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration.

FIG. 1 is one example of a block diagram briefly illustrating an electrical configuration of a memory-cell array portion of a NAND flash memory device. NAND flash memory device 1 is provided with a memory cell array configured by multiplicity of memory cells arranged in a matrix. Though not shown, components such as a peripheral circuit for performing read/write/erase operations to each memory cell and input/output interface circuit are provided in addition to the memory-cell array.

Memory cell array includes multiplicity of cell units UC. Unit memory cell UC includes select gate transistor Trs1 connected to bit line BL, select gate transistor Trs2 connected to source line SL, and 2^{k} (32 (=m) for example) number of memory-cell transistors Trm series connected between a couple of select gate transistors Trs1 and Trs2. Dummy cells may be series connected between a couple of select gate transistors Trs1 and Trs2 instead of the above described 2^{k} number of memory-cell transistors Trm. Gate electrodes MG of memory-cell transistors Trm aligned in the X direction and belonging to different cell units UC are electrically connected by word line WL.

A single block comprises a predetermined number of cell units UC aligned along the X direction (the row direction: the left and right direction as viewed in FIG. 1). Memory-cell array is formed of blocks aligned along the Y direction (the column direction: the up and down direction as viewed in FIG. 1). As illustrated, bit-line contacts CB are disposed in the regions between cell units UC adjacent in the Y direction where select gate transistors Trs1 face one another. Bit-line contact CB is connected to bit line BL disposed above it. Further, in the regions where select gate transistors Trs2 face one another, source lines SL are connected which interconnect cell units UC aligned in the X direction.

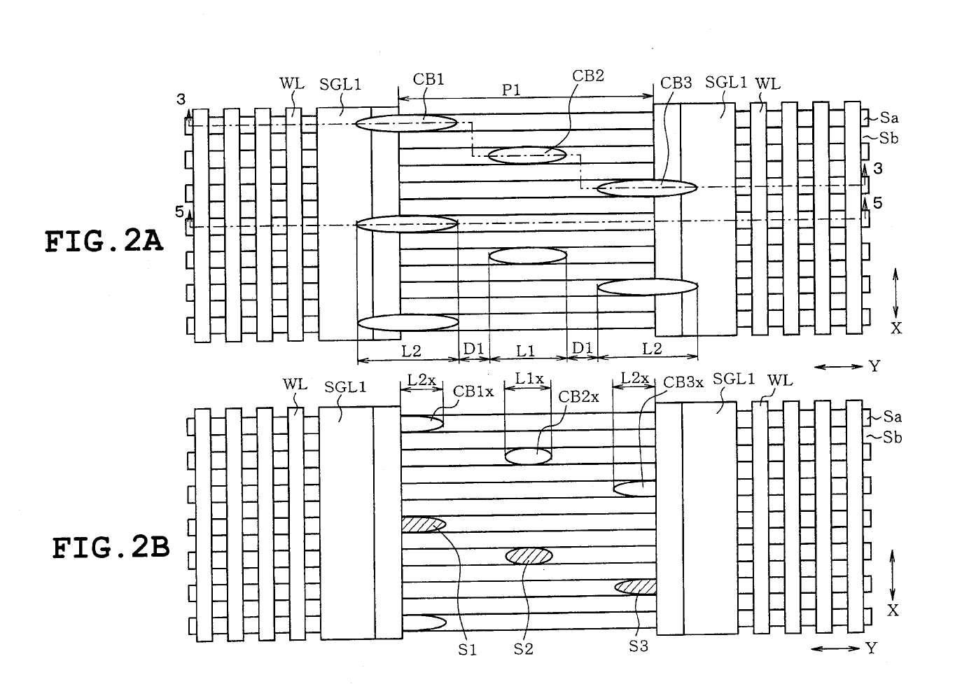

Gate electrodes SG of select gate transistors Trs1 of cell units UC aligned in the X direction are electrically connected by select gate line SGL1. Similarly, gate electrodes SG of select gate transistors Trs2 of cell units UC aligned in the X direction are electrically connected by select gate line SGL2. The sources of select gate transistors Trs2 are connected to a common source line SL. Select gate transistor Trs1 and Trs2 are referred to as select gate transistor Trs when describing the structures with reference to FIG. 2 and later figures.

FIGS. 2A and 2B are plan views illustrating the layout of a memory cell region in part. FIG. 2A illustrates the shape of an upper surface portion of bit-line contact CB and FIG. 2B illustrates the shape of a lower surface portion of bit-line contact CB.

As illustrated in FIGS. 2A and 2B, element isolation regions Sb are formed in the memory-cell region of a p-type silicon substrate 2 serving as a semiconductor substrate, so as to extend in the Y direction as viewed in FIG. 2A. Element isolation region Sb takes an STI (shallow trench isolation) structure in which element isolation trenches are filled with an insulating film. Element isolation regions Sb are spaced from one another in the X direction as viewed in FIG. 2A by a predetermined spacing. Thus, element regions Sa extending along the Y direction as viewed in FIG. 2A are formed in a surface layer portion of semiconductor substrate 2 so as to be isolated in the X direction. The widths of element region Sa and element isolation region Sb may be configured at or below the lithography resolution limit by a sidewall transfer technique, for example.

Word lines WL extend in a direction orthogonal to element regions Sa, that is, along the X direction as viewed in FIG. 2A. Word lines WL are formed so as to be spaced from one another in the Y direction as viewed in FIG. 2A by a predetermined spacing. In element regions Sa intersecting with word lines WL, gate electrodes MG of memory-cell transistors MT are formed.

The Y-direction adjacent memory-cell transistors MT form a part of a NAND string (memory string). Select gate transistor Trs is disposed in Y direction outer side of memory-cell transistor Trm located at each of the two ends of the NAND string so as to be located adjacent to memory-cell transistor Trm. Select-gate transistors Trs are aligned in the X direction and select gate electrodes SG of select gate transistors Trs are electrically connected by select gate line SGL1. Select gate electrodes SG of select gate transistors Trs are formed in element regions Sa intersecting with select gate lines SGL.

Bit-line contacts CB are formed above element regions Sa located between gate electrodes SG of cell units UC adjacent in the Y direction. The distance between adjacent gate electrodes SG is specified to P1. In the example of the first embodiment, three bit-line contacts CB1, CB2, and CB3 adjacent in the X direction are grouped as a single unit of layout pattern and are displaced from one another in the Y direction by a predetermined distance. Such layout pattern of three bit-line contacts CB1, CB2, and CB3 is repeated in the X direction.

The three bit-line contacts CB1, CB2, and CB3 of the layout pattern are each shaped like a flat ellipse in plan view. The X-direction diameters, i.e. the minor diameters, of each of the ellipse-shaped bit-line contacts (CB1, CB2, and CB3) are configured to be substantially equal to the width of element regions Sa. The Y direction diameters, i.e. the major diameters, of each of the ellipse-shaped bit-line contacts (CB1, CB2, and CB3) on the other hand, are configured to a dimension that secures sufficient area of contact with silicon substrate 2.

Among the three bit-line contacts CB1, CB2, and CB3 of the layout pattern, bit-line contact CB2 located in the middle has a major diameter of L1. Bit-line contact CB1 and bit-line contact CB3, located on different X direction sides of bit-line contact CB2 so as to be adjacent to bit-line contact CB2, are displaced by spacing D1 from bit-line contact CB2. Bit-line contact CB1 and bit-line contact CB3 both have major diameter L2 which is greater than L1. Both bit-line contact CB1 and bit-line contact CB3, located on the two Y-direction ends of the region between the adjacent gate electrodes SG, partially overlap with select gate electrodes SG so as to narrow the portion contacting silicon substrate 2. Bit-line contact CB1, CB2, and CB3 are laid out so that their area of contact S1, S2, and S3 with silicon substrate 2 are substantially equal as illustrated in FIG. 2B.

Though not illustrated, source contacts are disposed above element regions Sa located between the source-line side gate electrodes SG of cell units UC adjacent in the Y direction. The source contacts are disposed so as to be shared by cell units UC aligned in the X direction. More specifically, the source line contacts are disposed so as to extend across element regions Sa of the adjacent cell units UC and connect the adjacent element regions Sa. The spacing between gate electrodes SG is specified to a width that allows provision of at least one source contact.

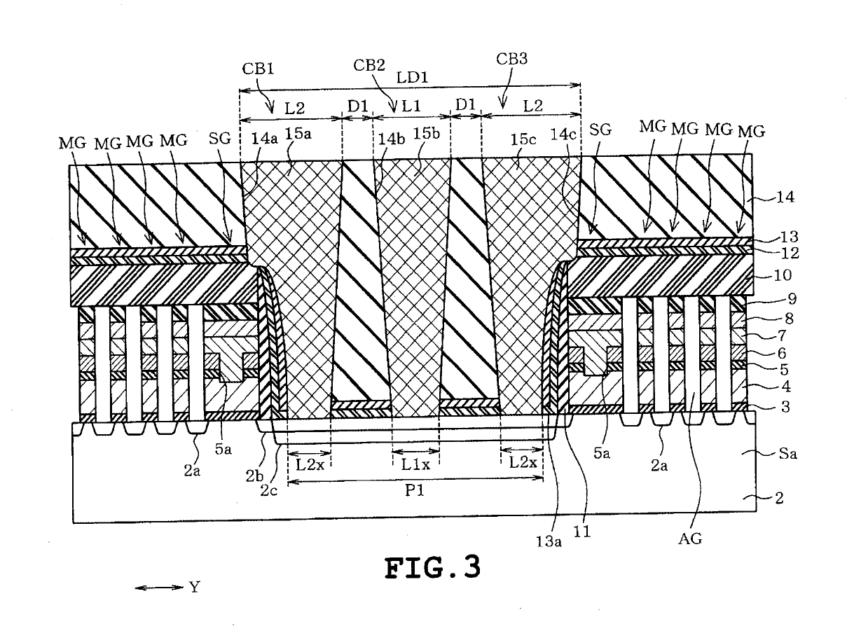

Next, a description will be given on the structures of memory-cell transistor trm, select gate transistor Trs, and bit-line contact CB in the memory-cell region with reference to FIG. 3. Gate insulating film 3 is formed above the upper surface of silicon substrate 2. Above the upper surface of gate insulating film 3, gate electrode MG of memory-cell transistor Trm and gate electrode SG of select gate transistor Trs are formed. Memory-cell transistor Trm is configured by gate insulating film 3, gate electrode MG, and source/drain region 2a formed into silicon substrate 2 located on both sides of gate electrode MG. Multiple memory-cell transistors Trm are formed so as to be adjacent to one another in the Y direction. Select transistor Trs is disposed adjacent to memory-cell transistor Trm located at each end of the string of memory-cell transistors Trm. Stated differently, memory-cell transistors Trm are disposed between a pair of select transistors Trs.

Gate electrode MG of memory-cell transistor Trm includes, above gate insulating film 3 also referred to as a tunnel oxide, polycrystalline silicon film 4 serving as floating gate electrode, interelectrode insulating film 5, polycrystalline silicon film 6 and 7 serving as a control gate electrode, metal film 8 formed of tungsten or the like, and silicon nitride film 9. An ONO (oxide-nitride-oxide) film, A NONON (nitride-oxide-nitride-oxide-nitride) film, or a high-dielectric-constant insulating film may be used as interelectrode insulating film 5.

Source/drain region 2a is provided in the surface layer of silicon substrate 2 located between gate electrodes MG and between gate electrode SG and gate electrode MG. LDD (lightly doped drain) region 2b serving as a drain region is provided in the surface layer of silicon substrate 2 located between gate electrodes SG. Source/drain region 2a and LDD region 2b may be formed by introducing impurities into the surface layer of silicon substrate 2. Further, drain region 2c heavily doped with impurities is formed into the surface layer of silicon substrate 2 located between gate electrodes SG. An LDD structure is formed in the above described manner.

The structure of gate electrode SG of select transistor Trs is substantially identical to the structure of gate electrode MG of memory-cell transistor Trm. Gate electrode SG includes, above gate insulating film 3, a stack of polycrystalline silicon film 4 serving as a lower layer electrode, interelectrode insulating film 5, polycrystalline silicon film 6 and 7 serving as an upper layer electrode, metal film 8, and silicon nitride film 9. Opening 5a is provided in the central portion of interelectrode insulating film 5 of gate electrode SG so that polycrystalline silicon film 4 contacts polycrystalline silicon films 6 and 7 through opening 5a and become electrically conductive with polycrystalline silicon films 6 and 7.

Insulating film 10 is provided above the upper surfaces of silicon nitride films 9 disposed at the uppermost portions of gate electrodes MG and SG. Insulating film 10 extends across the upper surfaces of gate electrodes MG and the upper surfaces of gate electrodes MG and SG so as not to completely fill the gaps between gate electrodes MG and between gate electrodes MG and SG. A silicon oxide film may be used for example as insulating film 10. The formation of insulating film 10 forms the so-called air gaps AG between gate electrodes MG and between gate electrode MG and SG. Air gap AG is a gap that achieves insulation without being filled with an insulating film.

Air gaps AG are not provide between gate electrodes SG. Instead, spacers 11 are formed along the sidewall surfaces of gate electrodes SG so as to be located in the gap between gate electrodes SG. A silicon oxide film may be used for example as spacer 11. Spacer 11 is formed so as to extend from the upper surface portion of gate electrode SG to the upper surface of silicon substrate 2.

Above insulating film 10, silicon oxide film 12 and silicon nitride film 13 are disposed so as to cover the surfaces of insulating film 10 and spacer films 11 disposed between gate electrodes SG, as well as the surfaces of silicon substrate 2 exposed in the gaps between gate electrodes SG. Interlayer insulating film 14 is further disposed above silicon nitride film 13 so as to fill the gaps between gate electrodes SG and so as to cover the upper surfaces of gate electrodes MG and gate electrodes SG.

Contact plug 15a, 15b, and 15c for bit-line contact CB1, CB2, and CB3 extend from the upper portion of interlayer insulating film 14 to the lower portion of interlayer insulating film 14 so as to penetrate through interlayer insulating film 14 and further through silicon nitride film 13 and silicon oxide film 12 so as to reach silicon substrate 2 located in the gap between gate electrodes SG. Contact plug 15a, 15b, and 15c are tapered (inclined) so that their diameters become smaller toward the surfaces of silicon substrate 2 from their upper surface portions. Contact plug 15a, 15b, and 15c may be formed of tungsten (W) or polycrystalline silicon film for example.

The middle contact plug 15b has a Y-direction diameter (major diameter) L1 when measured at its upper surface portion and a Y-direction diameter L1x less than L1 (L1x<L1) when measured at the portion contacting the surface of silicon substrate 2.

Diameter L1x is less than diameter L1 because the sidewalls surfaces of the contact hole are tapered. Contact plug 15a and contact plug 15c, located in either side of the contact plug 15b so as to be adjacent to the middle contact plug 15b, have major diameters L2 greater than L1 (L2>L1) when measured at their upper surfaces.

Further, one side of each of contact plug 15a and contact plug 15c, proximal to gate electrode SG, partially overlap with the sidewall and the upper surface of the adjacent gate electrode SG. Thus, the lower end portions of contact plug 15a and contact plug 15c are cutoff by the sidewall portion of the adjacent select gate electrode SG to reduce area S1 and area S3 of the portions of contact plug 15a and contact plug 15c contacting silicon substrate 2. As a result, the Y-direction length L2x of the portions of contact plug 15a and contact plug 15c contacting silicon substrate 2 approximates the Y-direction major diameter L1x of the portion of contact plug 15b contacting silicon substrate 2.

Further, in the portions of contact plug 15a and contact plug 15c overlapping with gate electrodes SG, silicon oxide film 12 and silicon nitride film 13 are partially removed at the transitional portion from the shoulder portion to the planar portion of gate electrode SG to expose insulating film 10.

The above described structure provides the following effects. The three bit-line contacts CB1, CB2, and CB3 displaced in the Y direction are grouped as a layout pattern, and bit-line contact CBL and bit-line contact CB3 at the two ends of the layout pattern are configured to have major diameter L2 greater than major diameter L1 of the middle bit-line contact CB2. Thus, it is possible to relax lithography constraints when forming contact holes of similar shapes and thereby allow bit-line contact CB1 and bit-line contact CB3 in the two sides to be disposed near (spacing D1) the middle bit-line contact CB2.

When major diameters L2 of bit-line contact CB1 and bit-line contact CB3 in the two sides are increased, the contact area with silicon substrate 2 would become greater than contact area S2 between the middle bit-line contact CB2 and silicon substrate S2. However, in the present embodiment, bit-line contact CB1 and bit-line contact CB3 in the two sides are configured to overlap with gate electrodes SG, and thus, the regions establishing contact with silicon substrate 2 are limited to contact area S1 and contact area S3 which are substantially equal to contact area S2 of the middle bit-line contact CB2. As a result, it is possible to reduce the distance between select gates SG to P1 and render the contact resistance to be substantially equal.

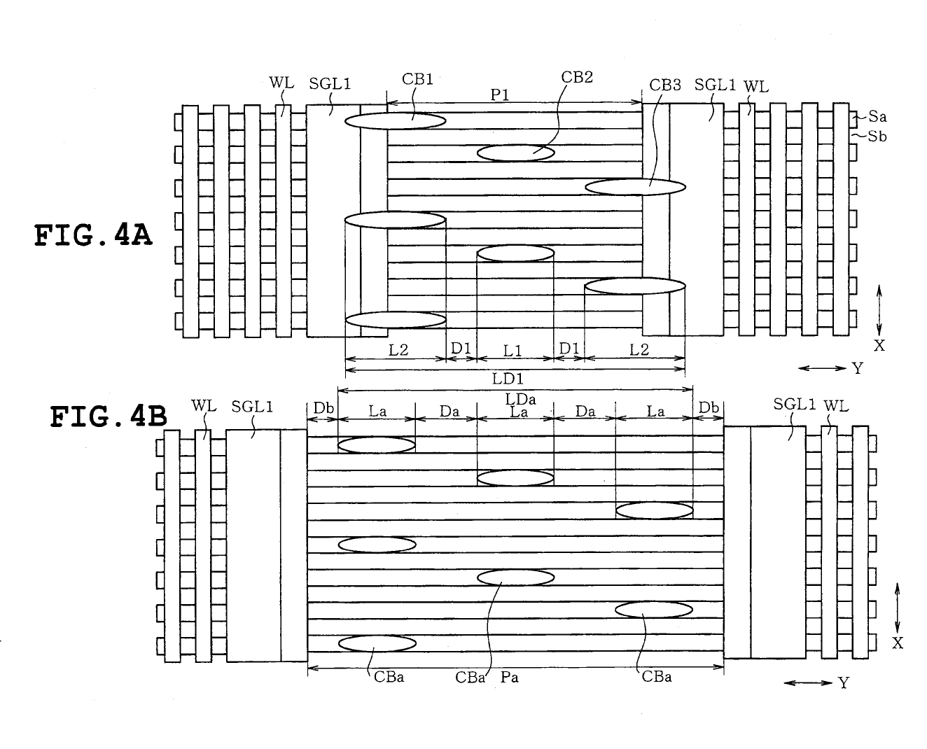

Next, a description will be given on the above described effects with reference to FIG. 4A and FIG. 4B and by comparison with a conventional structure. FIG. 4A corresponds to FIG. 2A of the present embodiment. FIG. 4B is a comparative view illustrating bit-line contacts CBa being formed by the conventional method. The dimension of bit-line contact CBa illustrated in FIG. 4B is equal to the dimension of the middle bit-line contact CB2 illustrated in FIG. 4A.

First, as illustrated in FIG. 4B, a group of three bit-line contacts CBa are disposed so as to be displaced in the Y direction from one another. The width (X-direction width) of element region Sa is specified to a dimension equal to or less than the exposure limit of lithography. Thus, in view of controlling the contact resistance with silicon substrate 2, an ellipse shape elongated in the Y direction and having a dimension in the width direction (X direction) being substantially equal to the width of element region Sa is employed as the shape of bit-line contact CBa. The Y-direction diameter (major diameter) La of bit-line contact CBa is configured to be equal to major diameter L1 of bit-line contact CB2 of the present embodiment.

From the standpoint of pattern formation of bit-line contact CBa, it is required to provide layout spacing Da to ensure that three adjacent bit-line contacts CBa having the same shapes can be patterned. Layout spacing Da is greater than layout spacing D1 of the present embodiment. This is because layout spacing D1 can be reduced by configuring major diameter L2 of bit-line contact CB1 and bit-line contact CB3 to be greater than major diameter L1 of middle bit-line contact CB2.

Supposing that major diameter L2 of bit-line contact CB1 and bit-line contact CB3 is greater than major diameter L1 of bit-line contact CB2 by ΔL, the following equation (1) can be derived since L1 is equal to La. Further, supposing that layout spacing D1 indicated in FIG. 4A is less than layout spacing Da indicated in FIG. 4B by ΔD, the following equation (2) can be derived.

L2=La+ΔL (1)

D1=Da−ΔD (2)

As a result, distance LD1 between the two end portions of the pattern configured by the three bit-line contacts CB1 to CB3 can be represented by the following equation (3).

$$\begin{matrix}LD 1 = L 1 + 2 L 2 + 2 D 1 \\ = 3 La + 2 Da + 2 ( Δ L - Δ D )\end{matrix} \qquad ( 3 )$$

On the other hand, in the conventional pattern illustrated in FIG. 4B, LDa is represented by the following equation.

LDa=3La+2Da (4)

Thus, the following equation (5) representing the relation between LD1 and LDa can be derived from equation (3) and equation (4).

LD1=LDa+2(ΔL−ΔD) (5)

Thus, it is possible to make LD1 less than LDa if the value inside the brackets in equation (5) satisfies the relation of ΔD>ΔL. That is, shrinking can be achieved by configuring distance ΔD to be less than ΔL, where ΔL represents the amount by which major diameter L2 of bit-line contact CB1 and bit-line contact CB3 at the two end portions are increased, and ΔD represents the amount by which distance D1 from the middle bit-line contact CB2 is reduced. It is possible to satisfy the above described relation as far as design is concerned and thus, it is possible to reduce distance LD1 between the two end portions of the present embodiment as compared to distance LDa conventionally required.

When contacts are formed on silicon substrate 2 with major diameter L2 of bit-line contact CB1 and bit-line contact CB3 in the two sides being specified as described above, the area of contact with silicon substrate 2 becomes uneven in the middle contact and the contacts in the two end portions. The resistance incurred by a bit-line contact is primarily occupied by contact resistance which is determined by area of contact with silicon substrate 2 and thus, a difference in contact area results in a difference in the resistance incurred by bit-line contact. Unevenness in the resistances of bit-line contacts is permissible if operation is not affected. The present embodiment is configured to make the resistances of bit-line contacts even. That is, bit-line contacts CB1 to CB3 are preferably configured so that areas of contact S1 to S3 with silicon substrate 2 are substantially equal.

In this respect, bit-line contact CB1 and bit-line contact CB3 are disposed so as to overlap with gate electrodes SG in the present embodiment. That is, when forming contact holes, gate electrodes SG are disposed so that bit-line contact CB1 and bit-line contact CB3 at the two end portions are partially cutoff by gate electrodes SG at the contact surface portion with silicon substrate 2. As a result, it is possible to control areas of contact S1 to S3 of the three bit-line contact CB1 to CB3 with silicon substrate 2 to be substantially equal.

Further, by limiting the contact area using gate electrode SG in the above described manner, distance P1 can be made further less than LD1 in the region between gate electrodes, where P1 is a distance obtained by excluding the portions of silicon substrate 2 surface that are cutoff by spacer 11, silicon oxide film 12, and silicon nitride film 13. In this example, the shrinking effect can be approximated to ΔL, where ΔL is the amount in which the dimension of the major diameter of bit-line contact CB1 and bit-line contact CB3 in the two sides are increased with respect to the middle bit-line contact CB2. Thus, the above described distance P1 can be approximated to the difference of LD1 and 2ΔL which is represented by the following equation (6).

$$\begin{matrix}P 1 \dot{{=}_{.}} LD 1 - 2 Δ L \\ = LDa - 2 Δ D\end{matrix} \qquad ( 6 )$$

In the conventional pattern illustrated in FIG. 4B on the other hand, select gate electrodes SG are each disposed outside LDa so as to be distanced by Db and thus, Pa is represented by the following equation (7).

Pa=LDa+2Db (7)

As a result, distance P1 of the present embodiment can be obtained by the following equation (8) in comparison with the conventional distance Pa. As a result the shrinking effect can be doubled.

P1≈Pa−2(ΔD+Db) (8)

Thus, the contact resistances of the three bit-line contacts CB1 to CB3 can be made substantially even while reducing width P1 of the region for forming the bit-line contacts by 2(ΔD+Db) as compared to Pa. As illustrated in FIG. 4B, significant shrinking is achieved from width Pa required in the conventional pattern.

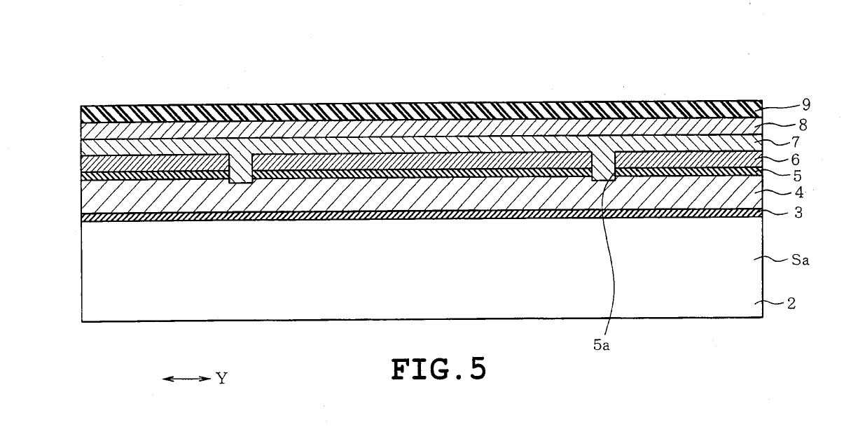

Next, a description will be given on one example of a manufacturing method of the above described structure with reference to FIGS. 5 to 12. The following description will focus on the features of the manufacturing method, however, known process steps may be added between the process steps or some of the process steps may be removed as required. Further, the process steps may be rearranged if practicable.

First, as illustrated in FIG. 5, film structures are formed above silicon substrate 2 for forming gate electrodes M G and SG. Process steps for obtaining these structures will be described briefly. Gate insulating film 3 is formed above silicon substrate 2 and polycrystalline silicon film 4 is formed thereafter. A silicon oxide film for example may be used as gate insulating film 3. Polycrystalline silicon film 4 serves as a floating gate electrode.

Above the upper surface of polycrystalline silicon film 4, a working insulating film is formed which is not illustrated. Then, a resist mask is formed by lithography which is used for forming element regions Sa and element isolation regions Sb. Then, using the resist mask, anisotropic etching is performed by RIE. As a result, the working insulating film, polycrystalline silicon film 4, and gate insulating film 3 are etched one after another and element isolation trenches are formed into silicon substrate 2.

Then, a coating-type silicon oxide film is formed so as to fill the formed element isolation trenches and the silicon oxide film formed above the working insulating film is removed by CMP (Chemical Mechanical Polishing). In case the working insulating film is formed of for example a silicon nitride film, the insulating film can be used as a stopper in the polishing by CMP. Thus, element isolation insulating films can be formed in the element isolation trenches. The working insulating film is thereafter removed. The above described process step delineates element regions Sa and element isolation regions Sb.

Then, interelectrode insulating film 5 and polycrystalline silicon film 6 are formed above the upper surface of polycrystalline silicon film 4. Interelectrode insulating film 5 may be formed for example by ONO film, NONON film, or an insulating film having high-dielectric-constant. Polycrystalline silicon film 6 may be formed by CVD. Then, boron for example is introduced into polycrystalline silicon film 6 by ion implantation to obtain a p-type polycrystalline silicon.

Next, openings 5a are formed by selectively removing portions of polycrystalline silicon film 6 and interelectrode insulating film 5 using lithography in locations corresponding to gate electrodes SG of select gate transistors Trs. Then, polycrystalline silicon film 7 is formed above the entire surface by CVD. As a result, polycrystalline silicon film 7 contacts polycrystalline silicon film 4 through opening 5a. Thus, polycrystalline silicon film 4 is electrically connected to polycrystalline silicon film 6 and polycrystalline silicon film 7. Next, metal film 8 and silicon nitride film 9 are formed one after the other. Tungsten (W) for example may be used as metal film 8 and may be formed by sputtering or the like. Silicon nitride film 9 may be formed by CVD. Tungsten nitride (WN) or the like serving as a barrier film may be formed between polycrystalline silicon film 7 and metal film 8. The structures illustrated in FIG. 5 are formed in the above described manner.

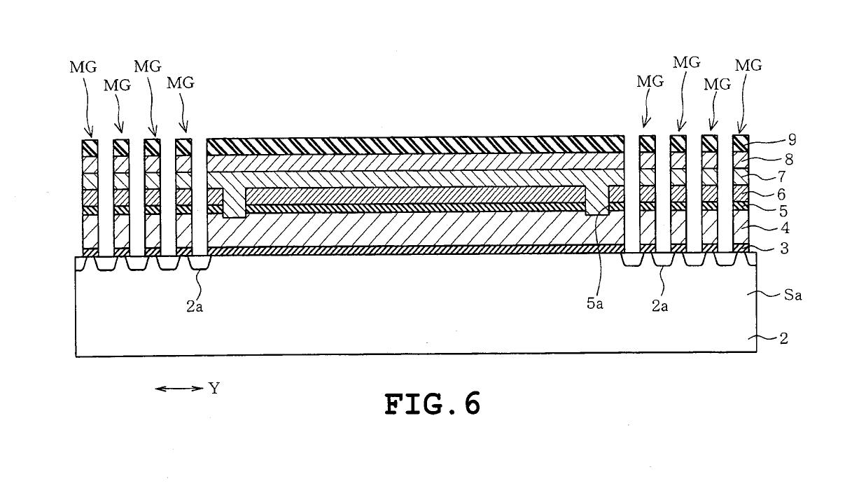

Next, as illustrated in FIG. 6, gate processing for forming gate electrodes MG of memory-cell transistors Trm is carried out using lithography. The gate processing of gate electrodes MG is carried out by anisotropic RIE using the resist pattern formed by lithography as an etch mask. The anisotropic etching etches silicon nitride film 9, metal film 8, polycrystalline silicon films 7 and 6, interelectrode insulating film 5, polycrystalline silicon film 4, and gate insulating film 3 one after another. The side surface of gate electrode SG of select gate transistor Trs facing memory-cell transistor Trm is also processed by the above described process step. Next, impurities are introduced into silicon substrate 2 located between gate electrodes MG and between gate electrodes MG and SG by ion implantation. Phosphorous may be used as an impurity. Source/drain region 2a of memory-cell transistor Trm is formed by the above described process step.

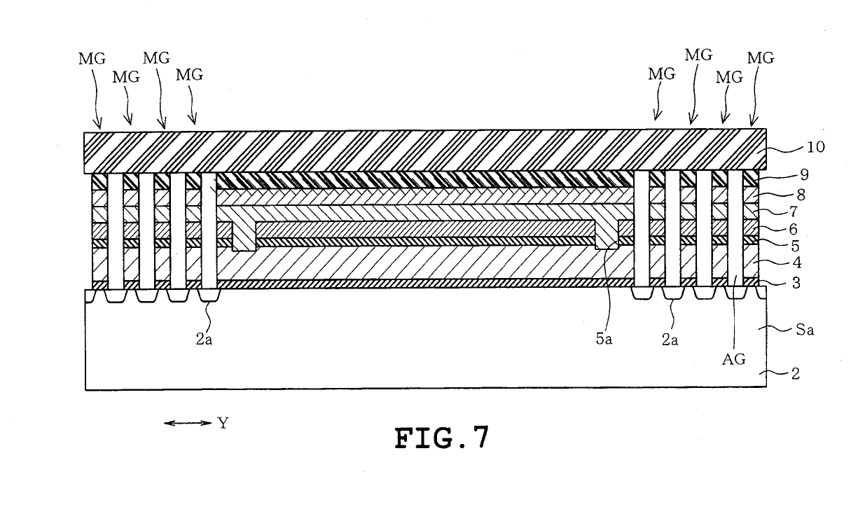

Next, as illustrated in FIG. 7, insulating film 10 for forming air gaps are formed above the entire surface. Insulating film 10 for forming air gaps comprises a silicon oxide film for example formed by CVD under conditions providing poor coverage. The spacing between gate electrodes MG of memory-cell transistors Trm and the spacing between gate electrode SG of select gate transistor Trs and gate electrode MG are narrow. Thus, insulating film 10 is formed so as to enclose the gaps between gate electrodes MG of memory-cell transistors Trm and between gate electrode SG of select gate transistor Trs and gate electrode MG, without filling the gaps between gate electrodes MG of memory-cell transistor Trm and between gate electrode SG of select gate transistor Trs and gate electrode MG.

As a result, it is possible to form air gaps AG unfilled by insulating film 10 between gate electrodes MG of memory-cell transistors Trm and between gate electrode SG of select gate transistor Trs and gate electrode MG. It is possible to reduce inter-wire capacitance between gate electrodes MG by the provision of air gaps AG.

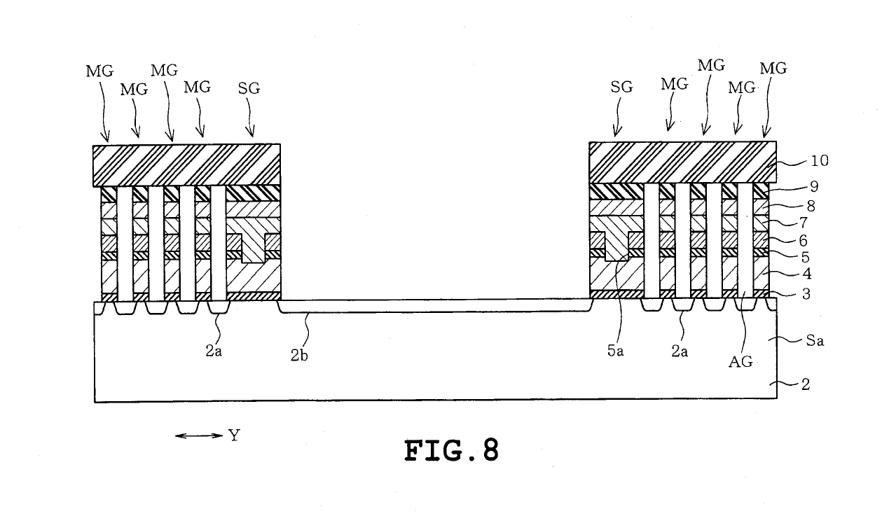

Next, as illustrated in FIG. 8, gate electrodes SG of select gate transistors Trs are formed. Anisotropic RIE is performed using lithography. In the anisotropic etching, insulating film 10 for forming unfilled gaps, silicon nitride film 9, metal film 8, polycrystalline silicon films 7 and 6, interelectrode insulating film 5, and polycrystalline silicon film 4 are etched one after another. Though not illustrated, gate processing of gate electrodes for peripheral circuit transistors is carried out simultaneously in the above described process step.

Then, using lithography and ion implantation, phosphorous for example is lightly doped in the source/drain region located in one side of electrodes SG of select gate transistors Trs facing another gate electrode SG. It is thus, possible to form lightly-doped source/drain regions 2b in LDD structures of transistors.

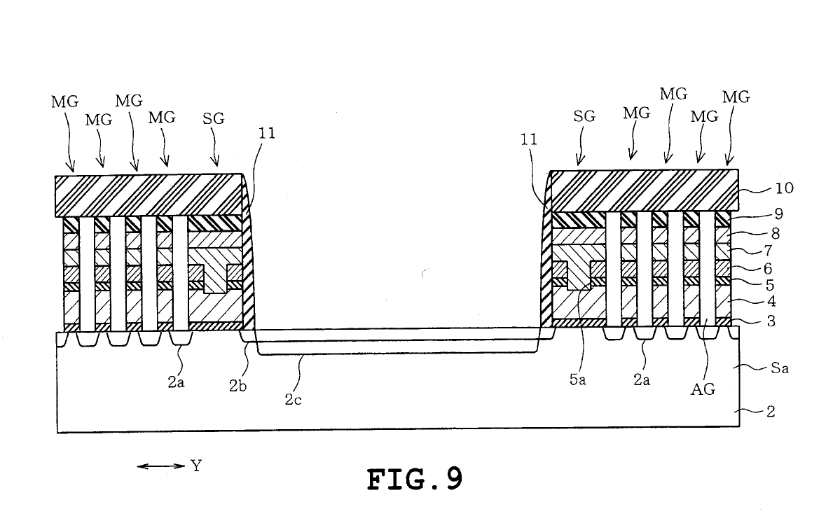

Next, as illustrated in FIG. 9, an insulating film formed of a silicon oxide film for example is formed in a predetermined thickness by CVD under conditions providing good coverage. Then, the entire surface is etched by anisotropic RIE to etch back the insulating film and thereby form spacers 11 along the side surfaces of gate electrodes SG facing the gap between gate electrodes SG. Spacer 11 extends from the location of the upper surface of insulating film 10 to the location of the surface of silicon substrate 2. Though not illustrated, the above described formation of spacers 11 also forms spacers along the sidewalls of gate electrodes of peripheral circuit transistors simultaneously.

Next, impurities are implanted by ion implantation in source/drain region located in one side of select gate transistors Trs facing another select gate transistor Trs. The impurities introduced is boron in this example and is introduced in a heavy dope. The impurities introduced by ion implantation are not introduced in the portions where spacers 11 are disposed. As a result, it is possible to form heavily-doped source/drain regions 2c in LDD structures of transistors.

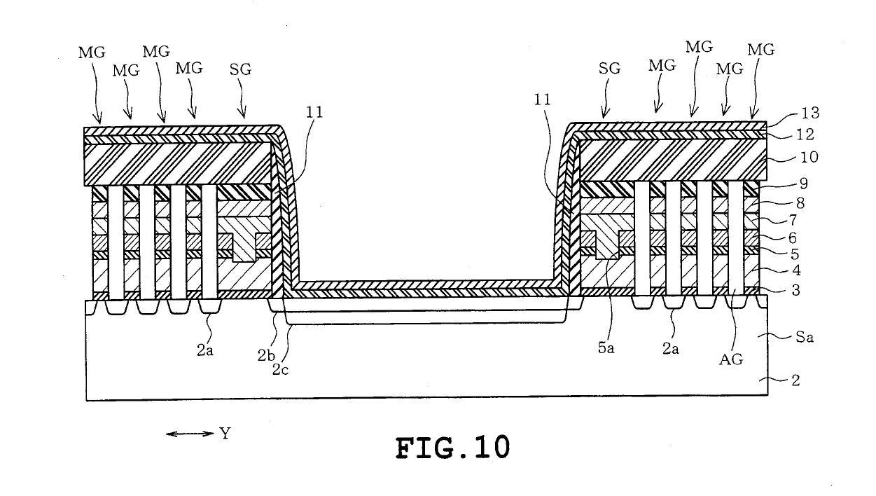

Then, as illustrated in FIG. 10, silicon oxide film 12 and silicon nitride film 13 are formed one after another so as to cover the upper surface portions of silicon substrate 2 subjected to the above described process step. Silicon oxide film 12 and silicon nitride film 13 can be formed by CVD. Thus, the upper surface of insulating 10 for forming unfilled gaps in the memory-cell region, the side surfaces of spacers 11 in the portions where select gate transistors Trs face one another, and the surface of silicon substrate 2 are covered by silicon oxide film 12 and silicon nitride film 13. Silicon nitride film 13 serves as a barrier film for preventing intrusion of moisture from the outside.

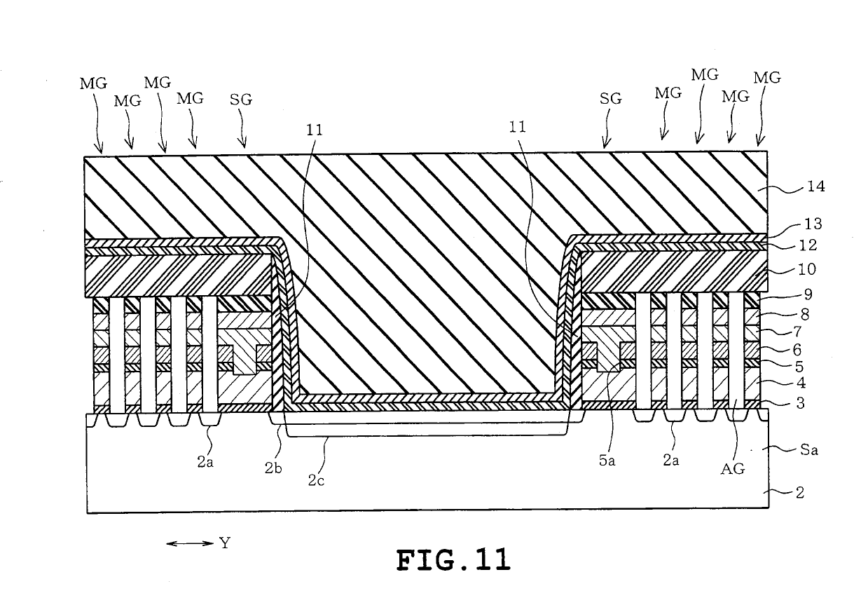

Then, as illustrated in FIG. 11, interlayer insulating film 14 is formed above the upper surface of silicon nitride film 13 formed in the above described process step. Interlayer insulating film 14 fills the recesses produced by the difference in the elevation of gate electrodes SG and silicon substrate 2. The upper surface of interlayer insulating film 14 is planarized. The planarization of interlayer insulating film 14 may be carried out by CMP polishing performed after interlayer insulating film 14 is formed. Interlayer insulating film 14 may be formed at once or may be formed in two different layers. When forming in two different layers, interlayer insulating film 14 may be formed for example by forming a fill insulating film for filling the recesses between gate electrodes SG, followed by planarization and formation of another interlayer insulating film.

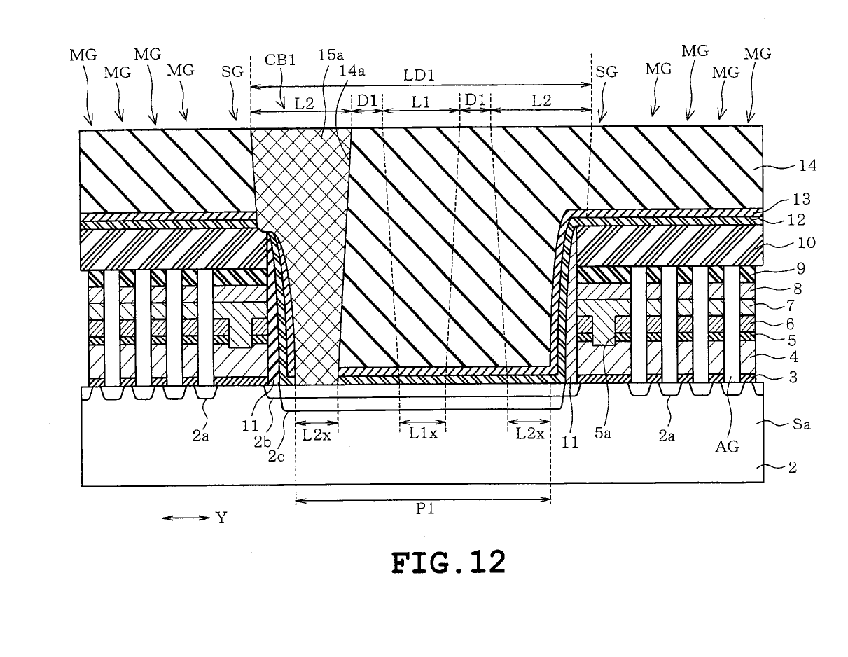

Then, as illustrated in FIG. 12, contact holes 14a to 14c are formed into interlayer insulating film 14. Contact holes 14a to 14c are formed so as to reach the surface of silicon substrate 2 from the upper surface of interlayer insulating film 14. FIG. 12 illustrates a cross section of a portion where contact hole 14a is provided. Contact holes 14a to 14c are patterned so that the dimensions of the patterns are specified to major diameters L2, L1, and L2 corresponding to the three bit-line contacts CB1, CB2, CB3, respectively. The layout spacing between contact holes 14a to 14b and between contact holes 14b to 14c are each specified to D1.

Total length LD1 spanning from contact hole 14a to contact hole 14c is greater than width P1 of silicon substrate 2 exposed at the surface portion. Thus, contact holes 14a and 14c on the two sides reach gate electrodes SG and spacers 11 as the etching progresses and thus, become partially opened from thereafter toward silicon substrate 2 side. By specifying the etch selectivity, silicon nitride film 13 is used as an etch stopper in etching silicon oxide film serving as interlayer insulating film 14.

As the etching progresses to the upper surface of silicon nitride film 13, the etch conditions are modified to etch silicon nitride film 13 and silicon oxide film 12 to expose the surface of silicon substrate 2. As a result, it is possible to selectively expose the surface of silicon substrate 2. In the portions where contact hole 14a and contact hole 14c partially overlap with and reach the upper portions of gate electrodes SG, silicon nitride film 13 and silicon oxide film 12 are etched to expose insulating film 10. However, even if silicon oxide film 12 and silicon nitride film 13 above the upper surfaces of gate electrodes SG are etched, gate electrodes SG can be prevented from being affected since insulating film 10 is formed to prevent gate electrodes SG from being directly exposed. Contact holes 14a to 14c reaching the surface portion of silicon substrate 2 are formed in the above described manner. The dimensions of the openings at the surface of silicon substrate 2 are specified so that the major diameters representing the Y-direction lengths of contact holes 14a, 14b, and 14c are L2x, L1x, and L2x, in the listed sequence as described earlier. Further, areas of the openings S1 to S3 are substantially equal.

Then, contact plugs 15a to 15c are formed inside contact holes 14a to 14c. In forming contact plugs 15a to 15c, a metal film is formed above the upper surface processed as described above and the metal film above interlayer insulating film 14 is removed by etch back or CMP while leaving the metal film inside contact holes 14a to 14c. For example, tungsten (W) film and titanium nitride (TiN) serving as a barrier film may be used as contact plugs 15a to 15c. Contact plugs 15a to 15c are formed by the above described process steps.

The NAND flash memory device of the first embodiment is formed by the above described manufacturing method.

In the NAND flash memory device as described above, a group of three bit-line contacts CBa are disposed so as to be displaced in the Y direction from one another and major diameters (Y direction diameters) L2 of bit-line contact CB1 and bit-line contact CB3 in the two ends are configured to be greater than major diameter L1 of the middle bit-line contact CB2. Thus, it is possible to relax lithography constraints when aligning patterns of the same shape and dispose bit-line contact CB1 and bit-line contact CB3 in the two sides near (distance D1) the middle bit-line contact CB2. As a result, the Y-direction distance LD1 of the three bit-line contacts CB1 to CB3 can be reduced compared to conventional structures and achieve space efficiency.

Further, when major diameters L2 of bit-line contact CB1 and bit-line contact CB3 in the two sides are increased, the area of contact with silicon substrate 2 would become greater than area of contact S2 between the middle bit-line contact CB2 and silicon substrate S2. However, in the present embodiment, bit-line contact CB1 and bit-line contact CB3 in the two sides are configured to overlap with gate electrodes SG, and thus, the regions establishing contact with silicon substrate 2 are limited to contact area S1 and contact area S3 which are substantially equal to contact area S2 of the middle bit-line contact CB2. As a result, it is possible to reduce the distance between select gates SG to P1 and render the contact resistance to be substantially equal.

Further, in the process step for forming bit-line contacts CB1 to CB3, it is possible to prevent the etching for forming contact holes 14a to 14c to progress further when reaching the upper surfaces of select gate electrodes SG by using silicon nitride film 13 as an etch stopper. Thus, it is possible to form contact hole 14a and contact hole 14c so as to overlap with select gate electrodes SG without damaging select gate electrodes SG. Further, it is possible to carry out the above described process step without providing a separate process step for inhibiting the progression of etching.

### Second Embodiment

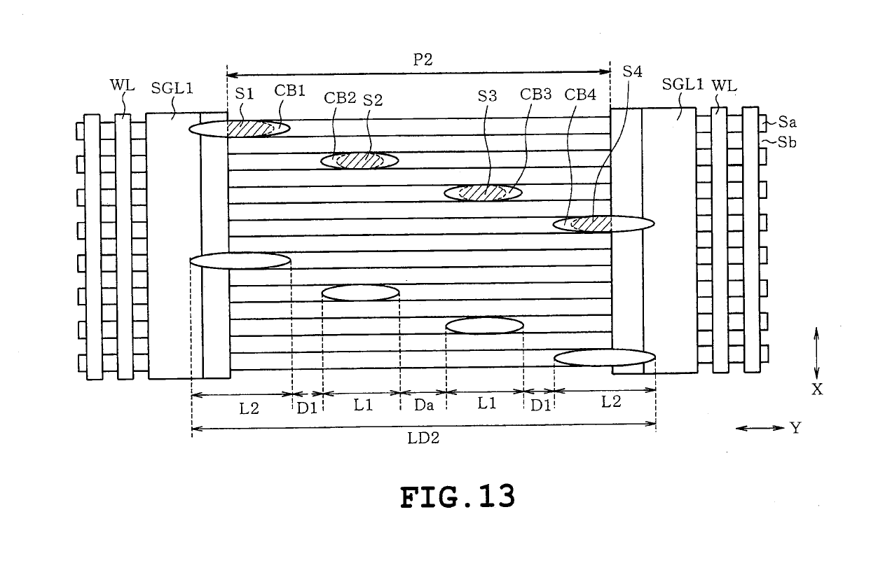

FIG. 13 illustrates a second embodiment. The difference from the first embodiment is that a group of four bit-line contacts are employed as a layout pattern. Thus, bit-line contacts in the same Y direction locations are formed with three element regions Sa disposed between them to allow wide space to be secured between the patterns in the lithography step as well.

In FIG. 13, the four bit-line contacts CB1 to CB4 are configured so that bit-line contact CB1 and bit-line contact CB4 in the two outer sides have major diameter L2 and bit-line contact CB2 and bit-line contact CB3 in the inner side have major diameter L1. Further, spacing D1 is provided between bit-line contact CB1 and bit-line contact CB2 and between bit-line contact CB3 and bit-line contact CB4 while spacing Da corresponding to conventional spacing is provided between bit-line contact CB2 and bit-line contact CB3.

In the two end portions, the total length LD2 is reduced by configuring the spacing to D1 and the major diameter to L2 as was the case in bit-line contact CB1 and bit-line contact CB3 of the first embodiment. Bit-line contact CB2 and bit-line contact CB3 in the inner side need to be formed under the conventional conditions.

By employing the above described structures, it is possible to obtain the following shrinking effects. Major diameter L2 of bit-line contact CB1 and bit-line contact CB4 and spacing D1 are specified according to equations (1) and (2) of the first embodiment and thus, distance LD2 between the two end portions of the pattern of four bit-line contacts CB1 to CB4 may be represented by the following equation (9).

$$\begin{matrix}LD 2 = 2 L 1 + 2 L 2 + 2 D 1 + Da \\ = 4 La + 3 Da + 2 ( Δ L - Δ D )\end{matrix} \qquad ( 9 )$$

On the other hand, when the layout of FIG. 13 is simulated in the conventional pattern, distance LDa between the two end portions of the four bit-line contacts CBa can be represented by the following equation (10).

LDa−4La+3Da (10)

Thus, the relation between LD2 and LDa can be represented by the following equation (11) based on equations (9) and (10).

LD2=LDa+2(ΔL−ΔD) (11)

Thus, as was the case in the first embodiment, it is possible to make distance LD2 between the two end portions in the present embodiment to be less than distance LDa conventionally required if the value inside the brackets in equation (11) satisfies the relation of ΔD>ΔL.

As was the case in the first embodiment, both bit-line contact CB1 and bit-line contact CB4 in the two sides can be can be disposed so as to overlap with gate electrodes SG in view of making the areas of contact S1 to S4 with silicon substrate 2 to be substantially equal. The areas of contact S1 to S4 can be made substantially equal by reducing the dimensions of bit-line contact CB1 and bit-line contact CB4 located in the two sides by ΔL by cutting off the dimensions in the direction of their major diameters by gate electrodes SG as was the case in the first embodiment. That is, distance P2 between gate electrodes SG can be approximated as represented by the following equation (12).

$$\begin{matrix}P 2 \dot{{=}_{.}} LD 2 - 2 Δ L \\ = LDa - 2 Δ D\end{matrix} \qquad ( 12 )$$

As a result, distance P2 of the present embodiment can be obtained by the following equation (13) in comparison with the conventional distance Pa. As a result the shrinking effect can be doubled even when a group of four bit-line contacts CB1 to CB4 are provided.

P2≈Pa−2(ΔD+Db) (13)

Thus, areas S1 to S4 of the portions of the four bit-line contacts CB1 to CB4 contacting silicon substrate 2 can be made substantially equal and thereby make the contact resistances of the four bit-line contacts CB1 to CB4 to be substantially equal.

It is possible to obtain the effects similar to those of the first embodiment in the second embodiment as well.

### OTHER EMBODIMENTS

The above described embodiments may be modified as follows.

In the first embodiment, the total length LD1 from bit-line contact CB1 to bit-line contact CB3 is configured to be less than the total length LDa in the conventional layout. However, the shrinking effect can be achieved even if LD1 is greater than LDa as long as distance P1 between gate electrodes SG is configured to be less than distance Pa of the conventional layout. The same is applicable to the second embodiment.

Further, in the first embodiment, the overlapping with select gate electrodes SG is optional in case the difference between the contact resistance incurred between bit-line contacts CB1 and CB3 and silicon substrate and the contact resistance incurred between bit-line contact CB2 and silicon substrate 2 are within a permissible range. It is possible to make the total length LD1 from bit-line contact CB1 to bit-line contact CB3 to be less than the total length LDa in the conventional layout by the above described approach as well.

In the above described embodiments, a group of three and a group of four bit-line contacts were discussed as examples of a layout pattern. A group of five or more bit-line contacts CB is also applicable. In such case, it is possible to obtain the shrinking effect of the total length LD and the shrinking effect of distance P between select gate electrodes SG.

Further, it is possible to obtain the shrinking effect of distance P by taking the advantage of the overlapping with gate electrodes SG in a layout pattern configured by a group of two bit-line contacts CB in which bit-line contacts CB are overlapped with gate electrodes SG by increasing the major diameter of each of the contact holes.

In each of the above described embodiments, the cross-section of bit-line contact CB is tapered. However, contact holes having small inclination angles may be provided by controlling the etching conditions as required.

A description was given through NAND flash memory device application, however, the same is applicable to semiconductor device in general in which contacts are established at the upper layer portion through multiple lower layer wirings and interlayer insulating films being arranged in lines and spaces.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device configured by memory-cell units aligned in a first direction and aligned in a second direction crossing the first direction over an insulating region, each of the memory-cell units having memory-cell transistors aligned in the first direction and select gate transistors located at two end portions thereof, the nonvolatile semiconductor storage device, comprising:
bit-line contacts extending through an interlayer insulating film disposed between two select gate transistors disposed so as to face one another in a portion where the memory-cell units reside adjacent to one another in the first direction and electrically connecting a semiconductor substrate with bit lines in upper layers;
wherein three or more of the bit-line contacts adjacent in the second direction and displaced from one another in the first direction are grouped as a layout pattern, and
wherein among the bit-line contacts of the layout pattern, bit-line contacts located at two end portions in the first direction are provided so as to overlap with gate electrodes of the select gate transistors via insulating films.

2. The nonvolatile semiconductor storage device according to claim 1, wherein areas of portions of the bit-line contacts of the layout pattern contacting the semiconductor substrate are substantially equal.

3. The nonvolatile semiconductor storage device according to claim 1, wherein among the bit-line contacts of the layout pattern, bit-line contacts located at two end portions in the first direction are patterned to have openings being wider in the first direction compared to other bit-line contacts.

4. The nonvolatile semiconductor storage device according to claim 3, wherein four or more bit-line contacts are grouped as the layout pattern and a spacing taken along the first direction between bit-line contacts located in two end portions in the first direction and bit-line contacts adjacent in the second direction is less than a spacing taken along the first direction between bit-line contacts other than the bit-line contacts located in the two end portions in the first direction.

5. The nonvolatile semiconductor storage device according to claim 1, wherein the insulating films are formed of insulating films different from the interlayer insulating film.

6. The nonvolatile semiconductor storage device according to claim 5, wherein the interlayer insulating film is formed of a silicon oxide film and the insulating films each include a silicon nitride film.

7. The nonvolatile semiconductor storage device according to claim 1, wherein the gate electrodes of the select gate transistors have sidewall insulating films formed along side surfaces thereof located in sides where the bit-line contacts are formed.

8. The nonvolatile semiconductor storage device according to claim 7, wherein the sidewall insulating films of the select gate transistors include silicon nitride films.

9. The nonvolatile semiconductor storage device according to claim 7, wherein the sidewall insulating films further extend along upper surfaces of gate electrodes of the memory-cell transistors, the sidewall insulating films being divided at regions where the bit-line contacts overlap with the gate electrodes of the select gate transistors.

10. The nonvolatile semiconductor storage device according to claim 1, wherein cross-sectional shapes of the bit-line contacts taken along a plane orthogonal to a direction penetrating through the interlayer insulating film are formed in ellipse shapes.

11. The nonvolatile semiconductor storage device according to claim 1, wherein the bit-line contacts are tapered so that sizes thereof are smaller at the semiconductor substrate surface than at an upper surface portion of the interlayer insulating film.

12. The nonvolatile semiconductor storage device according to claim 1, wherein a number of bit-line contacts of the layout pattern is 3 or more.

13. The nonvolatile semiconductor storage device according to claim 1, wherein the bit-line contacts are formed of tungsten.

14. The nonvolatile semiconductor storage device according to claim 1, wherein the bit-line contacts are formed of a metal via a barrier metal film.

15. A method of manufacturing a nonvolatile semiconductor storage device comprising:
forming a gate insulating film and a film for forming gate electrodes of memory-cell transistors and select gate transistors above a semiconductor substrate having element regions delineated by element isolation regions extending in a first direction;
forming memory gate electrodes and select gate electrodes by processing the film for forming gate electrodes;
forming spacers made of a first insulating film along sidewalls of the select gate electrodes located in sides where two select gate electrodes face one another in the first direction;
forming a barrier insulating film and an interlayer insulating film above upper surfaces of the memory gate electrodes and the select gate electrodes, the surfaces of the spacers, and above an upper surface of the semiconductor substrate located in a region where the two select gate electrodes face one another; and
forming contacts contacting the element regions into the interlayer insulating film located in the region where the two select gate electrodes face one another by etching contact holes through the interlayer insulating film using the barrier insulating film as a stopper,
wherein forming the contacts groups three or more contacts adjacent in a second direction crossing the first direction into a layout pattern so as to be displaced from one another in the first direction, and among the contacts of the layout pattern, contacts located at two end portions in the first direction are provided so as to overlap with gate electrodes of the select gate transistors via insulating films, and
wherein areas of portions of the contacts of the layout pattern contacting the semiconductor substrate are configured to be substantially equal.
